(19) United States
(12) Patent Application Publication
(10) Pub. No.: US 2025/0190643 A1
(43) Pub. Date: Jun. 12, 2025

(54) VEHICLE SIMULATION SYSTEM

(71) Applicant: GM Global Technology Operations LLC, Detroit, MI (US)

(72) Inventors: Luciano Lotufo Oetting, Washington Twp, MI (US); Joseph F. Szczerba, Grand Blanc, MI (US); Theodore James Williams, Macomb, MI (US); Joseph Patrick Jagodzinski, Hamtramck, MI (US); Christine M. Krolewski, Washington, MI (US); Michael E. Daniels, II, Oak Park, MI (US); Anthony A. Bosco, Macomb Twp., MI (US); Robert Ondrus, Northville, MI (US); Danni Zhang, Auburn Hills, MI (US); Jennifer A. Hullinger, Detroit, MI (US); Ramtin Parvizi, Windsor (CA); Roy J. Mathieu, Rochester Hills, MI (US); Tracey A. Wilt, Washington Township, MI (US); Robert Alan Dziurda, Waterford, MI (US); Stephen Rudofski, West Bloomfield, MI (US)

(21) Appl. No.: 18/531,081

(22) Filed: Dec. 6, 2023

(51) Int. Cl. G06F 30/15; B60N 2/16; B62D 1/18; G01M 17/007; G05G 1/40; G06T 19/00

(52) U.S. Cl. CPC G06F 30/15; G01M 17/007; G06T 19/006; B60N 2/16; B62D 1/18; G05G 1/40

(57) ABSTRACT

A vehicle simulation system for evaluating occupant ergonomic considerations related to driving position, spaciousness and access includes a seating buck adapted to provide a simulated interior environment of a vehicle by providing adjustable positions for a seat, a steering wheel and pedals, and an access module adapted to moveably support the seating buck therein and to provide an adjustable seat to ground height for the seating buck, adjustable dimensions of a simulated door opening and an adjustable position of the simulated door opening relative to the seating buck.

### INTRODUCTION

The present disclosure relates to a vehicle simulation system having a universal seating buck supported within an access module. Seating bucks are used to help vehicle designers evaluate ergonomic considerations for a passenger seated within the vehicle. Designers also want to evaluate such ergonomic considerations during ingress into and egress from the vehicle. Currently, to do so, designers will use a seat buck, simulating the location of the seat, steering wheel, pedals and dashboard and position the seat buck within a structure adapted to simulate body structure of the vehicle such as door opening, rocker panels and assist steps, wherein designers can evaluate the interior ergonomics of the vehicle as a passenger enters and exits the vehicle.

Designing in this way requires manufacture of specific parts for a stringer buck or full-size programmable vehicle (PVM) to simulate the dimensional characteristics of a specific vehicle platform. Thus, while current systems and methods achieve their intended purpose, there is a need for a new and improved system and method for evaluating ergonomic considerations of various design layouts using a vehicle simulator having a universal seating buck supported within an access module which allows dimensional vehicle characteristics such as door opening dimensions and rocker panel and assist step locations to be easily modified.

### SUMMARY

According to several aspects of the present disclosure, a vehicle simulation system for evaluating occupant ergonomic considerations related to driving position, spaciousness and access, includes a seating buck adapted to provide a simulated interior environment of a vehicle by providing adjustable positions for a seat, a steering wheel and pedals, and an access module adapted to moveably support the seating buck therein and to provide an adjustable seat to ground height for the seating buck, adjustable dimensions of a simulated door opening and an adjustable position of the simulated door opening relative to the seating buck.

According to another aspect, the access module further includes a plurality of vehicle body segments defining the simulated door opening including at least one upper door opening segment, at least one rear pillar segment, at least one front pillar segment, a door sill segment and an assist step segment, and a plurality of actuators, each one of the plurality of vehicle body segments attached to at least one of the plurality of actuators, each of the plurality of actuators in communication with a system controller and adapted to allow selective adjustment of a position of the attached one of the plurality of vehicle body segments.

According to another aspect, at least one of the plurality of vehicle body segments includes a pressure sensor adapted to detect contact with the at least one of the plurality of vehicle body segments by an occupant accessing the vehicle simulation system.

According to another aspect, the pressure sensor is adapted to measure an amount of force of any contact with the at least one of the plurality of vehicle body segments.

According to another aspect, the access module further includes a tumblehome mechanism having an upper gantry and a lower gantry, the at least one upper door opening segment and the at least one actuator to which the at least one upper door opening segment is attached being supported on the upper gantry of the tumblehome mechanism, the upper gantry of the tumblehome mechanism pivotally mounted onto the lower gantry of the tumblehome mechanism and adapted to allow selective angular adjustment of the at least one upper door opening segment relative to the seating buck, and the at least one rear pillar segment and the at least one actuator to which the at least one rear pillar segment is attached and the at least one front pillar segment and the at least one actuator to which the at least one front pillar segment is attached being supported on the lower gantry of the tumblehome mechanism, the lower gantry of the tumblehome mechanism adapted to allow selective lateral adjustment of the at least one upper door segment, the at least one rear pillar segment and the at least one front pillar segment relative to the seating buck.

According to another aspect, the system further includes a lifting mechanism, the seating buck supported on the lifting mechanism, the lifting mechanism adapted to selectively move the seating buck vertically up and down relative to the access module.

According to another aspect, the vehicle simulation system includes a vehicle design system and a virtual reality system, the vehicle design system and the virtual reality system adapted to receive real time input from the system controller related to position adjustments selectively made to the plurality of vehicle body segments of the access module and position adjustments selectively made to the position of the seat, steering wheel and pedals of the seating buck, the vehicle design system adapted to incorporate corresponding position adjustments to a vehicle design within the vehicle design system and the virtual reality system adapted to incorporate corresponding position adjustments to a virtual environment provided by the virtual reality system.

According to another aspect, the vehicle design system is further adapted to analyze aerodynamic, cost and mass considerations associated with position adjustments selectively made to the plurality of vehicle body segments of the access module and position adjustments selectively made to the position of the seat, steering wheel and pedals of the seating buck.

According to another aspect, the vehicle design system is adapted to automatically calculate and initiate additional position adjustments to the plurality of vehicle body segments of the access module and to the position of the seat, steering wheel and pedals of the seating buck based on design criteria when a position adjustment is selectively made to at least one of the plurality of vehicle body segments, the seat, the steering wheel and the pedals.

According to another aspect, the vehicle design system is further adapted to send position adjustments to a vehicle design within the vehicle design system to the system controller, wherein the system controller is adapted to actuate the plurality of actuators to make corresponding position adjustments to the plurality of vehicle body segments of the access module and to make corresponding position adjustments to the position of the seat, steering wheel and pedals of the seating buck.

According to several aspects of the present disclosure, a method for operating a vehicle simulation system for evaluating occupant ergonomic considerations related to driving position, spaciousness and access, includes providing, with a seating buck having adjustable positions for a seat, a steering wheel and pedals, a simulated interior environment of a vehicle, moveably supporting, with an access module, the seating buck, and providing, with the access module an adjustable seat to ground height for the seating buck, adjustable dimensions of a simulated door opening, and an adjustable position of the simulated door opening relative to the seating buck.

According to another aspect, the vehicle simulation system further includes a plurality of vehicle body segments defining a door opening including at least one upper door opening segment, at least one rear pillar segment, at least one front pillar segment, a door sill segment and an assist step segment, and a plurality of actuators, a one of the plurality of vehicle body segments attached to each one of the plurality of actuators, each of the plurality of actuators in communication with a system controller and adapted to allow selective adjustment of a position of the attached one of the plurality of vehicle body segments, wherein the providing, with the access module, adjustable simulated door opening dimensions, further includes actuating, with the system controller, at least one of the plurality of actuators, and adjusting, with the at least one of the plurality of actuators, a position of the attached one of the plurality of vehicle body segments.

According to another aspect, the method further includes detecting, with a pressure sensor mounted onto at least one of the plurality of vehicle body segments, contact with the at least one of the plurality of vehicle body segments by an occupant accessing the vehicle simulation system, and measuring, with the pressure sensor, an amount of force of any contact with the at least one of the plurality of vehicle body segments.

According to another aspect, the providing, with the access module, adjustable door opening dimensions further includes selectively adjusting an angular position of the at least one upper door opening segment relative to the seating buck with an upper gantry of a tumblehome mechanism onto which the at least one upper door opening segment, and the at least one actuator to which the at least one upper door opening segment is attached, is supported, and the providing, with the access module, an adjustable position of the simulated door opening relative to the seating buck further includes selectively adjusting a lateral position of the at least one upper door segment, the at least one rear pillar segment and the at least one front pillar segment relative to the seating buck with a lower gantry of the tumblehome mechanism onto which the upper gantry is pivotally mounted and onto which the at least one rear pillar segment and the at least one front pillar segment are mounted.

According to another aspect, the method further includes selectively moving, with a lifting mechanism onto which the seating buck is supported, the seating buck vertically up and down relative to the access module.

According to another aspect, the method further includes receiving, with a vehicle design system and a virtual reality system, real time input from the system controller related to position adjustments selectively made to the plurality of vehicle body segments of the access module and position adjustments selectively made to the position of the seat, steering wheel and pedals of the seating buck, incorporating, with the vehicle design system, corresponding position adjustments to a vehicle design within the vehicle design system, and incorporating, with the virtual reality system, corresponding position adjustments to a virtual environment provide by the virtual reality system.

According to another aspect, the method further includes analyzing, with the vehicle design system, aerodynamic, cost and mass considerations associated with position adjustments selectively made to the plurality of vehicle body segments of the access module and position adjustments selectively made to the position of the seat, steering wheel and pedals of the seating buck.

According to another aspect, the method further includes automatically calculating and initiating, with the vehicle design system, additional position adjustments to the plurality of vehicle body segments of the access module and to the position of the seat, steering wheel and pedals of the seating buck based on design criteria when a position adjustment is selectively made to at least one of the plurality of vehicle body segments, the seat, the steering wheel and the pedals.

According to another aspect, the method further includes sending, with the vehicle design system, position adjustments to a vehicle design within the vehicle design system to the system controller, and actuating, with the system controller, the plurality of actuators to make corresponding position adjustments to the plurality of vehicle body segments of the access module and to make corresponding position adjustments to the position of the seat, steering wheel and pedals of the seating buck.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way.

FIG. 1 is a schematic perspective view of a vehicle simulation system according to an exemplary embodiment of the present disclosure;

FIG. 2 is a schematic diagram of the system shown in FIG. 1;

FIG. 3 is a schematic perspective view of a seating buck of the vehicle simulation system according to an exemplary embodiment of the present disclosure;

FIG. 4 is a schematic perspective view of an access module of the vehicle simulation system according to an exemplary embodiment of the present disclosure;

FIG. 5 is a schematic side view of the access module shown in FIG. 4;

FIG. 6 is a schematic end view of the vehicle simulation system shown in FIG. 1; and

FIG. 7 is a flow chart illustrating a method according to an exemplary embodiment of the present disclosure.

The figures are not necessarily to scale and some features may be exaggerated or minimized, such as to show details of particular components. In some instances, well-known components, systems, materials or methods have not been described in detail in order to avoid obscuring the present disclosure. Therefore, specific structural and functional details disclosed herein are not to be interpreted as limiting, but merely as a basis for the claims and as a representative basis for teaching one skilled in the art to variously employ the present disclosure.

### DETAILED DESCRIPTION

The following description is merely exemplary in nature and is not intended to limit the present disclosure, application, or uses. Furthermore, there is no intention to be bound by any expressed or implied theory presented in the preceding technical field, background, brief summary or the following detailed description. It should be understood that throughout the drawings, corresponding reference numerals indicate like or corresponding parts and features. As used herein, the term module refers to any hardware, software, firmware, electronic control component, processing logic, and/or processor device, individually or in any combination, including without limitation: application specific integrated circuit (ASIC), an electronic circuit, a processor (shared, dedicated, or group) and memory that executes one or more software or firmware programs, a combinational logic circuit, and/or other suitable components that provide the described functionality. Although the figures shown herein depict an example with certain arrangements of elements, additional intervening elements, devices, features, or components may be present in actual embodiments. It should also be understood that the figures are merely illustrative and may not be drawn to scale.

As used herein, the term “vehicle” is not limited to automobiles. While the present technology is described primarily herein in connection with automobiles, the technology is not limited to automobiles. The concepts can be used in a wide variety of applications, such as in connection with aircraft, marine craft, other vehicles, and consumer electronic components.

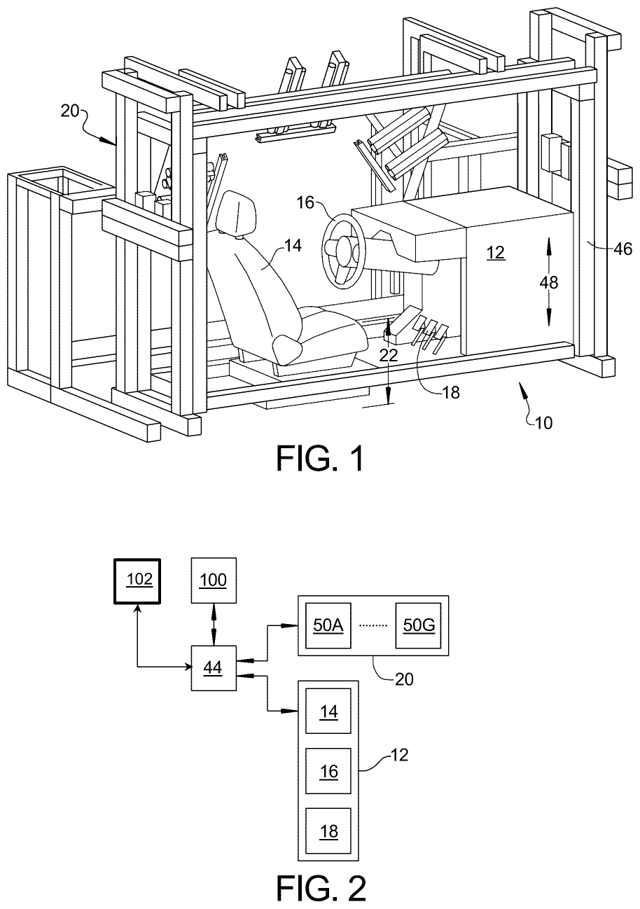

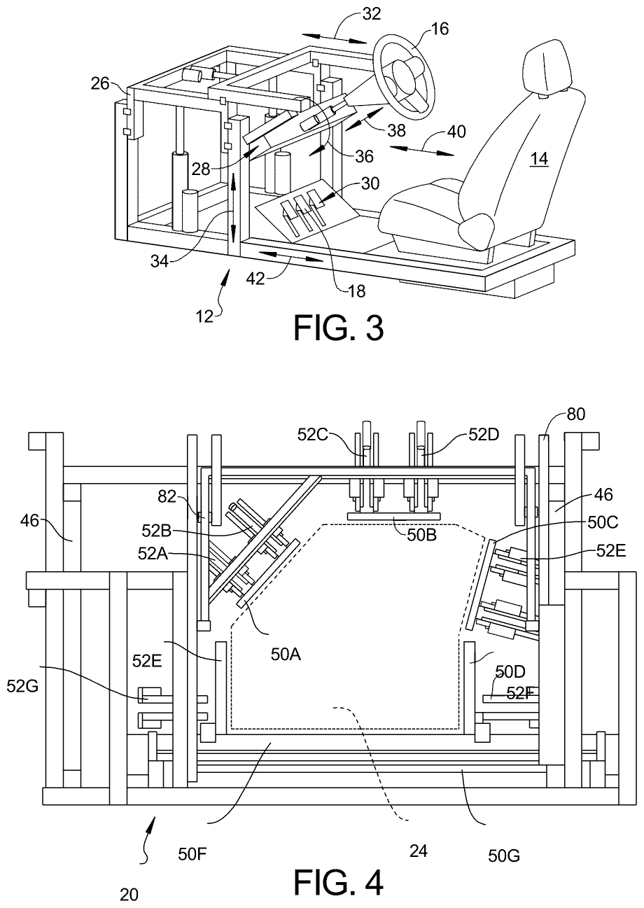

Referring to FIG. 1 and FIG. 2, a vehicle simulation system 10 for evaluating occupant ergonomic considerations related to driving position, spaciousness and access, includes a seating buck 12 adapted to provide a simulated interior environment of a vehicle by providing adjustable positions for a seat 14, a steering wheel 16 and pedals 18, and an access module 20 adapted to moveably support the seating buck 12 therein and to provide an adjustable seat to ground height 22 for the seating buck 12, adjustable dimensions of a simulated door opening 24 and an adjustable position of the simulated door opening 24 relative to the seating buck 12.

Vehicle package design is an integral part of the vehicle development process. It starts at the conceptual design stage and continues through the preliminary and final design stages. Vehicle package design consists of determining the occupant's spatial environment within a vehicle, including the location of the occupant with respect to the vehicle components, such as the seat 14, steering wheel 16 and pedals 18, the vehicle's mechanical spatial configuration and the overall exterior/interior dimensions, while meeting engineering and design specifications. The primary goal of the vehicle package design is the efficient and cost effective allocation of space that meets customer requirements. Developing and verifying a design package for a vehicle consists of defining the interior vehicle compartment configuration, dimensions and the physical location of the seat 14, steering wheel 16 and pedals 18 within the interior vehicle compartment.

Referring to FIG. 2, The seating buck 12 provides adjustable positions for the seat 14, steering wheel 16 and pedals 18 within a simulated interior occupant compartment to allow analysis and evaluation of the interior occupant compartment (head room, leg room, etc.), pedal packages, hand reach zones, driver's vision, ingress/egress, steering wheel location, and belt height, for verification of program targets, design criteria and assumptions.

In an exemplary embodiment, the seating buck 12 includes a frame 26 onto which a steering wheel assembly 28, a seat 14 and a pedal assembly 30 are supported. The steering wheel assembly 28 is selectively moveable relative to the frame 26 of the seating buck 12 horizontally, as indicated by arrow 32, and vertically, as indicated by arrow 34. The angular position of the steering wheel 16 is selectively moveable relative to the steering wheel assembly 28, as indicated by arrow 36, and a lateral position of the steering wheel 16 is selectively moveable relative to the steering wheel assembly 28, as indicated by arrow 38. The seat 14 is selectively moveable relative to the frame 26 of the seating buck 12 horizontally, as indicated by arrow 40. The pedal assembly 30 is selectively moveable relative to the frame 26 of the seating buck 12 horizontally, as indicated by arrow 42. Thus, the relative positions of the steering wheel 16, seat 14 and pedals 18 of the seating buck 12 can be selectively moved relative to one another, creating various arrangements for analysis and design considerations.

In an exemplary embodiment, the vehicle simulation system 10 includes a system controller 44 in communication with actuators within the seating buck 12, wherein the positions of the steering wheel assembly 28, the steering wheel 16, the pedal assembly 30 and the seat 14 may be selectively moved via input from a remotely located person using a human machine interface (keyboard, computer, tablet) to communicate with the system controller 44.

The system controller 44 is a non-generalized, electronic control device having a preprogrammed digital computer or processor, memory or non-transitory computer readable medium used to store data such as control logic, software applications, instructions, computer code, data, lookup tables, etc., and a transceiver [or input/output ports]. computer readable medium includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device. Computer code includes any type of program code, including source code, object code, and executable code.

As shown in FIG. 1, The seating buck 12 is supported within the access module 20. The access module 20 includes a lifting mechanism 46. The seating buck 12 is supported on the lifting mechanism 46, wherein the lifting mechanism 46 is adapted to allow selective movement of the seating buck 12 vertically up and down relative to the access module 20, as indicated by arrow 48, therein, allowing selective adjustment of a position of the seating buck 12 relative to the simulated door opening 24 and a position of the seating buck 12 relative to a ground surface for varying a seat to ground height 22 for the seating buck 12.

Referring to FIG. 4, the access module 20 includes features that define the simulated door opening 24. Movement, via the lifting mechanism 46, allows selective adjustment of the position of the seating buck 12 relative to the simulated door opening 24. In an exemplary embodiment, the features of the access module 20 that define the simulated door opening 24 include a plurality of vehicle body segments 50A-50G, including at least one upper door opening segment 50A, 50B, 50C, at least one rear pillar segment 50D, at least one front pillar segment 50E, a door sill segment 50F and an assist step segment 50G. As shown in FIG. 4, the access module 20 includes three upper door opening segments 50A, 50B, 50C, one rear pillar segment 50D, one front pillar segment 50E, one door sill segment 50F and one assist step segment 50G. Each of the vehicle body segments 50A-50G is selectively moveable so dimensions of the simulated door opening 24 can be adjusted. As shown, the simulated door opening 24 represents a side door of a vehicle through which an occupant enters/exits the simulated vehicle environment provided by the vehicle simulation system 10. The simulated door opening 24 could also be configured as a trunk or cargo bay opening, wherein the vehicle simulation system 10 would allow designers to test various configurations to evaluate ergonomic considerations associated with loading and unloading cargo within a simulated vehicle environment and load height considerations.

In an exemplary embodiment, the access module 20 includes a plurality of actuators 50, each one of the plurality of vehicle body segments being attached to at least one of the plurality of actuators. Each of the plurality of actuators is in communication with the system controller and adapted to allow selective adjustment of a position and/or orientation of the attached one of the plurality of vehicle body segments, thereby allowing the shape and dimensions of the simulated door opening to be changed.

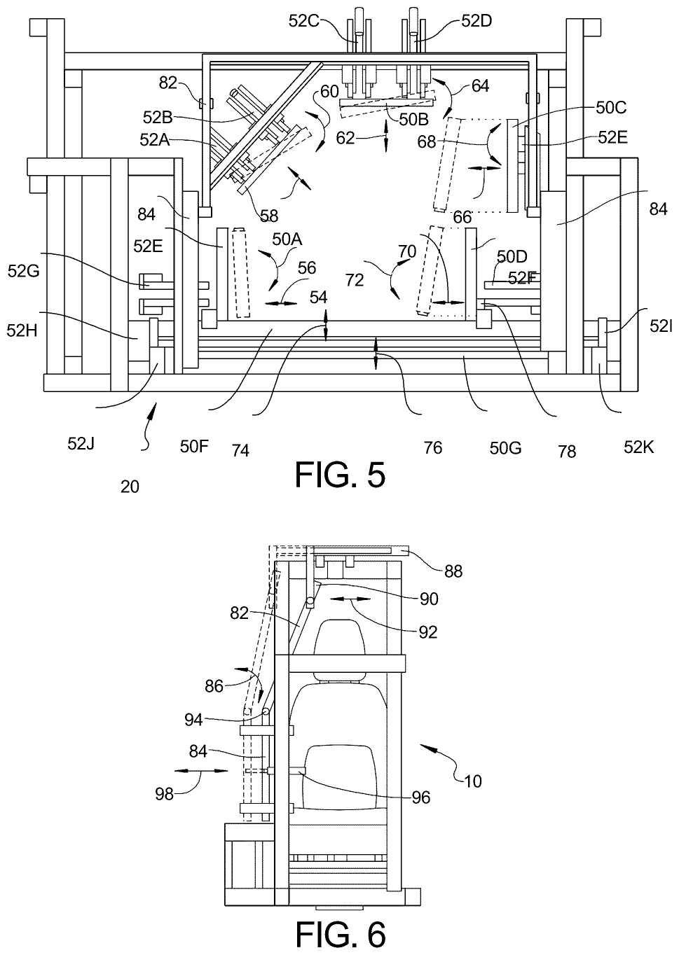

Referring to FIG. 5, a first upper door opening segment 50A is supported on two actuators 52A, 52B, wherein selective actuation of the actuators 52A, 52B allows the first upper door opening segment 50A to be moved back and forth laterally, as indicated by arrow 54, and allows rotational orientation of the first upper door opening segment 50A to be adjusted, as indicated by arrow 56. A second upper door opening segment 50B is supported on two actuators 52C, 52D, wherein selective actuation of the actuators 52C, 52D allows the second upper door opening segment 50B to be moved back and forth laterally, as indicated by arrow 58, and allows rotational orientation of the second upper door opening segment 50B to be adjusted, as indicated by arrow 60. A third upper door opening segment 50C is pivotally supported on an actuator 52E, wherein selective actuation of the actuator 52E allows the third upper door opening segment 50C to be moved back and forth laterally, as indicated by arrow 62, and allows rotational orientation of the third upper door opening segment 50C to be adjusted, as indicated by arrow 64. The rear pillar segment 50D is pivotally supported on an actuator 52F, wherein selective actuation of the actuator 52F allows the rear pillar segment 50D to be moved back and forth laterally, as indicated by arrow 66, and allows rotational orientation of the rear pillar segment 50D to be adjusted, as indicated by arrow 68. The front pillar segment 50E is pivotally supported on an actuator 52G, wherein selective actuation of the actuator 52G allows the front pillar segment 50E to be moved back and forth laterally, as indicated by arrow 70, and allows rotational orientation of the front pillar segment 50E to be adjusted, as indicated by arrow 72. The door sill segment 50F is supported on a pair of actuators 52H, 52I, wherein selective actuation of the actuators 52H, 52I allows the door sill segment 50F to be moved vertically up and down, as indicated by arrow 74. The assist step segment 50G is supported on a pair of actuators 52J, 52K, wherein selective actuation of the actuators 52J, 52K allows the assist step segment 50G to be moved vertically up and down, as indicated by arrow 76.

In an exemplary embodiment, at least one of the plurality of vehicle body segments 50A-50G includes a pressure sensor 78 adapted to detect contact with the at least one of the plurality of vehicle body segments 50A-50G by an occupant accessing the vehicle simulation system 10. The pressure sensor 78 is in communication with the system controller 44 so that, when testing the configuration, when an occupant passes through the simulated door opening 24 to simulate entering and exiting a vehicle, data from the pressure sensor 78 will detect when the occupant makes contact with the at least one vehicle segment 50A-50G. Further, in another exemplary embodiment, the pressure sensor 78 is adapted to measure an amount of force of any contact with the at least one of the plurality of vehicle body segments 50A-50G. Thus, during testing of a configuration, data is sent to the system controller 44 related to contact and the amount of force of such contact for evaluation of the ergonomics of the simulated door opening 24 configuration.

Referring to FIG. 6, in an exemplary embodiment, the access module 20 further includes a tumblehome mechanism 80 having an upper gantry 82 and a lower gantry 84, the at least one upper door opening segment 50A, 50B, 50C and the at least one actuator 52A-52E to which the at least one upper door opening segment 50A, 50B, 50C is attached being supported on the upper gantry 82 of the tumblehome mechanism 80. Referring to FIG. 4 and FIG. 5, as shown, the first upper door opening segment 50A and the two actuators 52A, 52B onto which the first upper door opening segment 50A are supported are mounted onto the upper gantry 82 of the tumblehome mechanism 80, the second upper door opening segment 50B and the two actuators 52C, 52D onto which the second upper door opening segment 50B are supported are mounted onto the upper gantry 82 of the tumblehome mechanism 80, and the third upper door opening segment 50C and the actuator 52E onto which the third upper door opening segment 50C is supported are mounted onto the upper gantry 82 of the tumblehome mechanism 80.

Referring again to FIG. 6, the upper gantry 82 of the tumblehome mechanism 80 is pivotally mounted onto the lower gantry 84 of the tumblehome mechanism 80, wherein the upper gantry 82 moves pivotally, as indicated by arrow 86, relative to the lower gantry 84, and thus, allows selective angular adjustment of the first upper door opening segment 50A, the second upper door opening segment 50B and the third upper door opening segment 50C relative to the seating buck 12. As shown, an actuator 88 is attached to an upper end 90 of the upper gantry 82 for selective horizontal movement of the upper end 90 of the upper gantry 82 relative to the lower gantry 84, as indicated by arrow 92, causing the upper gantry 82 to pivot about a connection point 94 between the upper gantry 82 and the lower gantry 84, and thus pivotally moving the upper gantry 82 relative to the lower gantry 84, as indicated by arrow 86.

Referring again to FIG. 5, the rear pillar segment 50D and the actuator 52F to which the at least one rear pillar segment 50D is attached and the front pillar segment 50E and the actuator 52G to which the front pillar segment 50E is attached are mounted onto the lower gantry 84 of the tumblehome mechanism 80. The lower gantry 84 of the tumblehome mechanism 80 being attached to an actuator 96 adapted to move the lower gantry 84 of the tumblehome mechanism 80 laterally back and forth, as indicated by arrow 98. Thus, simultaneous actuation of the actuator 88 attached to the upper end 90 of the upper gantry 82 and the actuator 96 attached to the lower gantry 84 will move the entire tumblehome mechanism 80 laterally back and forth, as indicated by arrow 98, thus allowing selective lateral adjustment of the first, second and third upper door segments 50A, 50B, 50C, the rear pillar segment 50D and the front pillar segment 50E relative to the seating buck 12, and laterally moving the simulated door opening 24 relative to the seating buck 12.

In another exemplary embodiment, the vehicle simulation system 10 includes a vehicle design system 100 in communication with the system controller 44, wherein the vehicle design system 100 is adapted to receive real time input from the system controller 44 related to position adjustments selectively made to the plurality of vehicle body segments 50A-50G of the access module 20 and position adjustments selectively made to the position of the seat 14, steering wheel 16 and pedals 18 of the seating buck 12, and make corresponding position adjustments to a vehicle design within the vehicle design system 100. Thus, as designers working with the seating buck 12 and the access module 20 make changes to the physical configuration of the seat 14, pedals 18 and steering wheel 16 of the seating buck 12 and to the plurality of vehicle body segments 50A-50G of the access module 20, such changes are automatically received by the vehicle design system 100 and incorporated into CAD designs within the vehicle design system 100. The vehicle design system 100 is adapted to automatically calculate the impact of such design changes to the overall vehicle design and analyze aerodynamic, cost and mass considerations associated with position adjustments selectively made to the plurality of vehicle body segments 50A-50G of the access module 20 and position adjustments selectively made to the position of the seat 14, steering wheel 16 and pedals 18 of the seating buck 12 to provide real-time feedback to designers using the vehicle simulation system 10.

In an exemplary embodiment, the vehicle design system 100 is adapted to automatically calculate and initiate additional position adjustments to the plurality of vehicle body segments 50A-50G of the access module 20 and to the position of the seat 14, steering wheel 16 and pedals 18 of the seating buck 12 based on design criteria when a position adjustment is selectively made to at least one of the plurality of vehicle body segments 50A-50G, the seat 14, the steering wheel 16 and the pedals 18. For example, if designers using the vehicle simulation system 10 make an adjustment that lowers the second vehicle body segment 50B, the vehicle design system 100 automatically calculates a corresponding adjustment to be made to the door sill segment 50F to maintain a minimum vertical dimension of the simulated door opening 24 that is part of the design criteria, and automatically initiates the actuators 52H, 52I supporting the door sill segment 50F to make the adjustment within the access module 20.

In another exemplary embodiment, the vehicle design system 100 is further adapted to send position adjustments to a vehicle design within the vehicle design system 100 to the system controller 44, wherein the system controller 44 is adapted to actuate the plurality of actuators 52A-52K to make corresponding position adjustments to the plurality of vehicle body segments 50A-50F of the access module 20 and to make corresponding position adjustments to the position of the seat 14, steering wheel 16 and pedals 18 of the seating buck 12. Thus, as designers work on a CAD design of a vehicle, possibly at a location remote from the seating buck 12 and access module 20, such changes are automatically sent to the system controller 44 which automatically makes corresponding adjustments to the seating buck 12 and access module 20 for physical testing by designers using the seating buck 12 and access module 20 to asses such changes. This allows designers working with the seating buck 12 and access module 20 at a lab, to see and analyze, in real time, changes incorporated by designers using the vehicle design system 100 software at remote offices.

The vehicle simulation system 10 allows real time two-way communication between designers using the seating buck 12 and access module 20 and designers using vehicle design system 100 software. In another exemplary embodiment the vehicle simulation system 10 further includes a virtual reality system 102 in communication with the system controller 44. The virtual reality system provides an immersive virtual environment for an occupant. With the virtual reality system 102, the vehicle simulation system 10 can be utilized with virtual reality technology and driver simulation technology to allow designers using the vehicle simulation system 10 to see how changes made to the position of the plurality of vehicle body segments 50A-50F of the access module 20 and changes made to the position of the seat 14, steering wheel 16 and pedals 18 of the seating buck 12 are experienced by an occupant with full visual immersion and g-force simulation. Thus, as an occupant physically seated within the vehicle simulation system 10 makes changes to the physical configuration of the seat 14, pedals 18 and steering wheel 16 of the seating buck 12 and to the plurality of vehicle body segments 50A-50G of the access module 20, such changes are automatically received by the virtual reality system 102 and incorporated, in real time, into the virtual environment provided to the occupant by the virtual reality system 102.

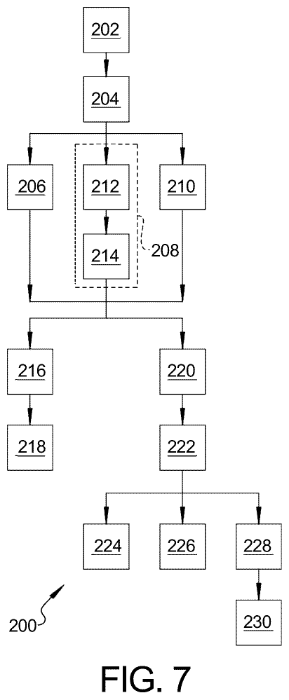

Referring to FIG. 7, a method 200 of operating a vehicle simulation system 10 for evaluating occupant ergonomic considerations related to driving position, spaciousness and access, includes, beginning at block 202, providing, with a seating buck 12 having adjustable positions for a seat 14, a steering wheel 16 and pedals 18, a simulated interior environment of a vehicle, moving to block 204, moveably supporting, with an access module 20, the seating buck 12, and, providing, with the access module 20, moving from block 204 to block 206, an adjustable seat to ground height 22 for the seating buck 12, moving from block 204 to block 208, adjustable dimensions of a simulated door opening 24, and, moving from block 204 to block 210, an adjustable position of the simulated door opening 24 relative to the seating buck 12.

In an exemplary embodiment, the vehicle simulation system 10 further includes a plurality of vehicle body segments 50A-50G defining a simulated door opening 24 including at least one upper door opening segment 50A, 50B, 50C, at least one rear pillar segment 50D, at least one front pillar segment 50E, a door sill segment 50F and an assist step segment 50G, and a plurality of actuators 52A-52K, a one of the plurality of vehicle body segments 50A-50G attached to each one of the plurality of actuators 52A-52K, each of the plurality of actuators 52A-52K in communication with a system controller 44 and adapted to allow selective adjustment of a position of the attached one of the plurality of vehicle body segments 50A-50G, wherein the providing, with the access module 20, adjustable simulated door opening 24 dimensions at block 208 further includes, moving to block 212, actuating, with the system controller 44, at least one of the plurality of actuators 52A-52K, and, moving to block 214, adjusting, with the at least one of the plurality of actuators 52A-52K, a position of the attached one of the plurality of vehicle body segments 50A-50G.

In an exemplary embodiment, the method further includes, moving to block 216, detecting, with a pressure sensor 78 mounted onto at least one of the plurality of vehicle body segments 50A-50G, contact with the at least one of the plurality of vehicle body segments 50A-50G by an occupant accessing the vehicle simulation system 10, and, moving to block 218, measuring, with the pressure sensor 78, an amount of force of any contact with the at least one of the plurality of vehicle body segments 50A-50G.

In an exemplary embodiment, the providing, with the access module, adjustable simulated door opening 24 dimensions at block 208 further includes selectively adjusting an angular position of the at least one upper door opening segment 50A, 50B, 50C relative to the seating buck 12 with an upper gantry 82 of a tumblehome mechanism 80 onto which the at least one upper door opening segment 50A, 50B, 50C, and the at least one actuator 52A-52E to which the at least one upper door opening segment 50A, 50B, 50C is attached, is supported, and, the providing, with the access module 20, an adjustable position of the simulated door opening 24 relative to the seating buck 12 at block 210 further includes selectively adjusting a lateral position of the at least one upper door segment 50A, 50B, 50C, the at least one rear pillar segment 50D and the at least one front pillar segment 50E relative to the seating buck 12 with a lower gantry 84 of the tumblehome mechanism 80 onto which the upper gantry 82 is pivotally mounted and onto which the at least one rear pillar segment 50D and the at least one front pillar segment 50E are mounted.

In another exemplary embodiment, the providing, with the access module 20 an adjustable seat to ground height 22 for the seating buck 12 at block 206 and an adjustable position of the simulated door opening 24 relative to the seating buck 12 at block 210 further includes selectively moving, with a lifting mechanism 46 onto which the seating buck 12 is supported, the seating buck 12 vertically up and down relative to the access module 20.

In another exemplary embodiment, the method 200 further includes, moving to block 220, receiving, with a vehicle design system 100, real time input from the system controller 44 related to position adjustments selectively made to the plurality of vehicle body segments 50A-50G of the access module 20 and position adjustments selectively made to the position of the seat 14, steering wheel 16 and pedals 18 of the seating buck 12, and, moving to block 222, making, with the vehicle design system 100, corresponding position adjustments to a vehicle design within the vehicle design system 100.

In an exemplary embodiment, the method 200 further includes, moving from block 222 to block 224, analyzing, with the vehicle design system 100, aerodynamic, cost and mass considerations associated with position adjustments selectively made to the plurality of vehicle body segments 50A-50G of the access module 20 and position adjustments selectively made to the position of the seat 14, steering wheel 16 and pedals 18 of the seating buck 12.

In an exemplary embodiment, the method 200 further includes, moving from block 222 to block 226, automatically calculating and initiating, with the vehicle design system 100, additional position adjustments to the plurality of vehicle body segments 50A-50G of the access module 20 and to the position of the seat 14, steering wheel 16 and pedals 18 of the seating buck 12 based on design criteria when a position adjustment is selectively made to at least one of the plurality of vehicle body segments 50A-50G, the seat 14, the steering wheel 16 and the pedals 18.

In another exemplary embodiment, the method 200 further includes, moving from block 222 to block 228, sending, with the vehicle design system 100, position adjustments to a vehicle design within the vehicle design system 100 to the system controller 44, and, moving to block 230, actuating, with the system controller 44, the plurality of actuators 52A-52K to make corresponding position adjustments to the plurality of vehicle body segments 50A-50G of the access module 20 and to make corresponding position adjustments to the position of the seat 14, steering wheel 16 and pedals 18 of the seating buck 12.

A system and method of the present disclosure offers several advantages. These include the ability to create different configurations of an interior space for a vehicle as well as a simulated door opening for evaluation of ergonomic and manufacturing considerations without having to build a unique, single use model to do so. A system of the present disclosure allows various configurations to be tested and evaluated and is portable, so it can be moved between locations. Further, a system of the present disclosure can communicate with a vehicle design system that is remotely located, wherein two-way communication between the vehicle design system and the system controller allows changes within one of the seating buck/access module and the vehicle design system to be automatically communicated to the other of the seating buck/access module and vehicle design system.

The description of the present disclosure is merely exemplary in nature and variations that do not depart from the gist of the present disclosure are intended to be within the scope of the present disclosure. Such variations are not to be regarded as a departure from the spirit and scope of the present disclosure.

What is claimed is:

1. A vehicle simulation system for evaluating occupant ergonomic considerations related to driving position, spaciousness and access, comprising:
a seating buck adapted to provide a simulated interior environment of a vehicle by providing adjustable positions for a seat, a steering wheel and pedals; and
an access module adapted to moveably support the seating buck therein and to provide an adjustable seat to ground height for the seating buck, adjustable dimensions of a simulated door opening and an adjustable position of the simulated door opening relative to the seating buck.

2. The system of claim 1, wherein the access module further includes:
a plurality of vehicle body segments defining the simulated door opening including at least one upper door opening segment, at least one rear pillar segment, at least one front pillar segment, a door sill segment and an assist step segment; and
a plurality of actuators, each one of the plurality of vehicle body segments attached to at least one of the plurality of actuators, each of the plurality of actuators in communication with a system controller and adapted to allow selective adjustment of a position of the attached one of the plurality of vehicle body segments.

3. The system of claim 2, wherein at least one of the plurality of vehicle body segments includes a pressure sensor adapted to detect contact with the at least one of the plurality of vehicle body segments by an occupant accessing the vehicle simulation system.

4. The system of claim 3, wherein the pressure sensor is adapted to measure an amount of force of any contact with the at least one of the plurality of vehicle body segments.

5. The system of claim 2, wherein the access module further includes a tumblehome mechanism having an upper gantry and a lower gantry, the at least one upper door opening segment and the at least one actuator to which the at least one upper door opening segment is attached being supported on the upper gantry of the tumblehome mechanism, the upper gantry of the tumblehome mechanism pivotally mounted onto the lower gantry of the tumblehome mechanism and adapted to allow selective angular adjustment of the at least one upper door opening segment relative to the seating buck, and the at least one rear pillar segment and the at least one actuator to which the at least one rear pillar segment is attached and the at least one front pillar segment and the at least one actuator to which the at least one front pillar segment is attached being supported on the lower gantry of the tumblehome mechanism, the lower gantry of the tumblehome mechanism adapted to allow selective lateral adjustment of the at least one upper door segment, the at least one rear pillar segment and the at least one front pillar segment relative to the seating buck.

6. The system of claim 5, further including a lifting mechanism, the seating buck supported on the lifting mechanism, the lifting mechanism adapted to selectively move the seating buck vertically up and down relative to the access module.

7. The system of claim 2, wherein the vehicle simulation system includes a vehicle design system and a virtual reality system;
the vehicle design system and the virtual reality system adapted to receive real time input from the system controller related to position adjustments selectively made to the plurality of vehicle body segments of the access module and position adjustments selectively made to the position of the seat, steering wheel and pedals of the seating buck;
the vehicle design system adapted to incorporate corresponding position adjustments to a vehicle design within the vehicle design system; and
the virtual reality system adapted to incorporate corresponding position adjustments to a virtual environment provided by the virtual reality system.

8. The system of claim 7, wherein the vehicle design system is further adapted to analyze aerodynamic, cost and mass considerations associated with position adjustments selectively made to the plurality of vehicle body segments of the access module and position adjustments selectively made to the position of the seat, steering wheel and pedals of the seating buck.

9. The system of claim 7, wherein the vehicle design system is adapted to automatically calculate and initiate additional position adjustments to the plurality of vehicle body segments of the access module and to the position of the seat, steering wheel and pedals of the seating buck based on design criteria when a position adjustment is selectively made to at least one of the plurality of vehicle body segments, the seat, the steering wheel and the pedals.

10. The system of claim 7, wherein the vehicle design system is further adapted to send position adjustments to a vehicle design within the vehicle design system to the system controller, wherein the system controller is adapted to actuate the plurality of actuators to make corresponding position adjustments to the plurality of vehicle body segments of the access module and to make corresponding position adjustments to the position of the seat, steering wheel and pedals of the seating buck.

11. A method for operating a vehicle simulation system for evaluating occupant ergonomic considerations related to driving position, spaciousness and access, comprising:
providing, with a seating buck having adjustable positions for a seat, a steering wheel and pedals, a simulated interior environment of a vehicle;
moveably supporting, with an access module, the seating buck; and
providing, with the access module:
an adjustable seat to ground height for the seating buck;
adjustable dimensions of a simulated door opening; and
an adjustable position of the simulated door opening relative to the seating buck.

12. The method of claim 11, wherein the vehicle simulation system further includes:
a plurality of vehicle body segments defining a door opening including at least one upper door opening segment, at least one rear pillar segment, at least one front pillar segment, a door sill segment and an assist step segment; and
a plurality of actuators, a one of the plurality of vehicle body segments attached to each one of the plurality of actuators, each of the plurality of actuators in communication with a system controller and adapted to allow selective adjustment of a position of the attached one of the plurality of vehicle body segments;
wherein the providing, with the access module, adjustable simulated door opening dimensions further includes:
actuating, with the system controller, at least one of the plurality of actuators; and
adjusting, with the at least one of the plurality of actuators, a position of the attached one of the plurality of vehicle body segments.

13. The method of claim 12, further including:
detecting, with a pressure sensor mounted onto at least one of the plurality of vehicle body segments, contact with the at least one of the plurality of vehicle body segments by an occupant accessing the vehicle simulation system; and
measuring, with the pressure sensor, an amount of force of any contact with the at least one of the plurality of vehicle body segments.

14. The method of claim 12, wherein:
the providing, with the access module, adjustable door opening dimensions further includes selectively adjusting an angular position of the at least one upper door opening segment relative to the seating buck with an upper gantry of a tumblehome mechanism onto which the at least one upper door opening segment, and the at least one actuator to which the at least one upper door opening segment is attached, is supported; and
the providing, with the access module, an adjustable position of the simulated door opening relative to the seating buck further includes selectively adjusting a lateral position of the at least one upper door segment, the at least one rear pillar segment and the at least one front pillar segment relative to the seating buck with a lower gantry of the tumblehome mechanism onto which the upper gantry is pivotally mounted and onto which the at least one rear pillar segment and the at least one front pillar segment are mounted.

15. The method of claim 14, further including selectively moving, with a lifting mechanism onto which the seating buck is supported, the seating buck vertically up and down relative to the access module.

16. The method of claim 12, further including:
receiving, with a vehicle design system and a virtual reality system, real time input from the system controller related to position adjustments selectively made to the plurality of vehicle body segments of the access module and position adjustments selectively made to the position of the seat, steering wheel and pedals of the seating buck;
incorporating, with the vehicle design system, corresponding position adjustments to a vehicle design within the vehicle design system; and
incorporating, with the virtual reality system, corresponding adjustments to a virtual environment provided by the virtual reality system.

17. The method of claim 16, further including analyzing, with the vehicle design system, aerodynamic, cost and mass considerations associated with position adjustments selectively made to the plurality of vehicle body segments of the access module and position adjustments selectively made to the position of the seat, steering wheel and pedals of the seating buck.

18. The method of claim 16, further including automatically calculating and initiating, with the vehicle design system, additional position adjustments to the plurality of vehicle body segments of the access module and to the position of the seat, steering wheel and pedals of the seating buck based on design criteria when a position adjustment is selectively made to at least one of the plurality of vehicle body segments, the seat, the steering wheel and the pedals.

19. The method of claim 16, further including:
sending, with the vehicle design system, position adjustments to a vehicle design within the vehicle design system to the system controller; and
actuating, with the system controller, the plurality of actuators to make corresponding position adjustments to the plurality of vehicle body segments of the access module and to make corresponding position adjustments to the position of the seat, steering wheel and pedals of the seating buck.

20. A vehicle simulation system for evaluating occupant ergonomic considerations related to driving position, spaciousness and access, comprising:
a seating buck adapted to provide a simulated interior environment of a vehicle by providing adjustable positions for a seat, a steering wheel and pedals;
an access module adapted to moveably support the seating buck therein and to provide an adjustable seat to ground height for the seating buck and adjustable door opening dimensions, the access module including:
a plurality of vehicle body segments defining a door opening including at least one upper door opening segment, at least one rear pillar segment, at least one front pillar segment, a door sill segment and an assist step segment; and
a plurality of actuators, a one of the plurality of vehicle body segments attached to each one of the plurality of actuators, each of the plurality of actuators in communication with a system controller and adapted to allow selective adjustment of a position of the attached one of the plurality of vehicle body segments;
a tumblehome mechanism having an upper gantry and a lower gantry, the at least one upper door opening segment and the at least one actuator to which the at least one upper door opening segment is attached being supported on the upper gantry of the tumblehome mechanism, the upper gantry of the tumblehome mechanism pivotally mounted onto the lower gantry of the tumblehome mechanism and adapted to allow selective angular adjustment of the at least one upper door opening segment relative to the seating buck, and the at least one rear pillar segment and the at least one actuator to which the at least one rear pillar segment is attached and the at least one front pillar segment and the at least one actuator to which the at least one front pillar segment is attached being supported on the lower gantry of the tumblehome mechanism, the lower gantry of the tumblehome mechanism adapted to allow selective lateral adjustment of the at least one upper door segment, the at least one rear pillar segment and the at least one front pillar segment relative to the seating buck;
a lifting mechanism, the seating buck supported on the lifting mechanism, the lifting mechanism adapted to selectively move the seating buck vertically up and down relative to the access module;
at least one of the plurality of vehicle body segments including a pressure sensor adapted to detect contact with the at least one of the plurality of vehicle body segments by an occupant accessing the vehicle simulation system and to measure an amount of force of any contact with the at least one of the plurality of vehicle body segments; and
a vehicle design system and a virtual reality system adapted to:
receive real time input from the system controller related to position adjustments selectively made to the plurality of vehicle body segments of the access module and position adjustments selectively made to the position of the seat, steering wheel and pedals of the seating buck, and incorporate corresponding position adjustments to a vehicle design within the vehicle design system and to a virtual environment provided by the virtual reality system;
analyze aerodynamic, cost and mass considerations associated with position adjustments selectively made to the plurality of vehicle body segments of the access module and position adjustments selectively made to the position of the seat, steering wheel and pedals of the seating buck;
automatically calculate and initiate additional position adjustments to the plurality of vehicle body segments of the access module and to the position of the seat, steering wheel and pedals of the seating buck based on design criteria when a position adjustment is selectively made to at least one of the plurality of vehicle body segments, the seat, the steering wheel and the pedals; and
send position adjustments to a vehicle design within the vehicle design system to the system controller, wherein the system controller is adapted to actuate the plurality of actuators to make corresponding position adjustments to the plurality of vehicle body segments of the access module and to make corresponding position adjustments to the position of the seat, steering wheel and pedals of the seating buck.
